(19) United States
(12) Patent Application Publication
(10) Pub. No.: US 2024/0322067 A1
(43) Pub. Date: Sep. 26, 2024

(54) APPARATUS AND METHOD FOR MANUFACTURING DISPLAY APPARATUS

(71) Applicant: Samsung Display Co., LTD., Yongin-si (KR)

(72) Inventors: Jongyoon LEE, Yongin-si (KR); Sokwon NOH, Yongin-si (KR)

(21) Appl. No.: 18/387,111

(22) Filed: Nov. 6, 2023

(30) Foreign Application Priority Data
Mar. 24, 2023 (KR) 10-2023-0039095
Jun. 14, 2023 (KR) 10-2023-0076420

(51) Int. Cl. H01L 33/00

(52) U.S. Cl. CPC H01L 33/005; H01L 2933/0075

(57) ABSTRACT

An apparatus for manufacturing a display apparatus includes: an evaporation source including a nozzle configured to spray a deposition material, a first frame arranged on the evaporation source and defining a trench therein, and a first angle limiting plate arranged in the trench of the first frame and defining a plurality of slits therein, where the trench extends in a lengthwise direction of the first frame.

This application claims priority to Korean Patent Application No. 10-2023-0039095, filed on Mar. 24, 2023 and Korean Patent Application No. 10-2023-0076420, filed on Jun. 14, 2023, and all the benefits accruing therefrom under 35 U.S.C. § 119, the contents of which in their entirety are herein incorporated by reference.

### BACKGROUND

### 1. Field

One or more embodiments relate to an apparatus and method for manufacturing a display apparatus. More particularly, one or more embodiments relate to an apparatus and method for manufacturing a display apparatus, the apparatus including an angle limiting plate for adjusting a spraying angle of a nozzle.

### 2. Description of the Related Art

A display apparatus displays an image by receiving information about the image. A process of manufacturing the display apparatus includes a process of depositing various types of thin films having a thickness of several nanometers to several micrometers.

Thermal evaporation in the thin-film deposition may include a process of evaporating and/or sublimating a deposition material by heating the deposition material and then spraying the deposition material onto a substrate by using a nozzle. The deposition material in contact with the substrate having a relatively low temperature may be condensed on the substrate to form a layer. For smooth evaporation, sublimation, and spraying of the deposition material, an evaporation source may have to maintain a high temperature.

### SUMMARY

Above an evaporation source, an angle limiting plate for adjusting a spraying angle of a nozzle may be arranged on opposite ends of the nozzle or around the nozzle. The evaporation source maintains a high temperature, and thus, heat transfer may occur in the angle limiting plate arranged on an upper end of the evaporation source. Thus, a temperature of a surface of the angle limiting plate may rise.

A portion of a deposition material sprayed by the nozzle may be blocked by the angle limiting plate, and thus, may not reach a substrate and may be disposed on the surface of the angle limiting plate. When a surface temperature of the angle limiting plate is increased due to heat transfer from the evaporation source, the deposition material disposed on the surface of the angle limiting plate may be evaporated or sublimated again and may be placed on a spraying path of the deposition material sprayed by the nozzle. In this case, the deposition material evaporated from the surface of the angle limiting plate may interrupt the spraying path of the deposition material sprayed by the nozzle, and thus, smooth deposition may become difficult.

One or more embodiments include an apparatus for manufacturing a display apparatus and a method of manufacturing a display apparatus, where the apparatus includes an angle limiting plate defining a plurality of slits therein to interrupt heat transfer so that a surface temperature of the angle limiting plate is effectively reduced. However, this is an example, and the scope of the disclosure is not limited thereto.

Additional aspects will be set forth in part in the description which follows and, in part, will be apparent from the description, or may be learned by practice of the presented embodiments of the disclosure.

According to one or more embodiments, an apparatus for manufacturing a display apparatus includes: an evaporation source including a nozzle configured to spray a deposition material, a first frame arranged on the evaporation source and defining a trench therein, and a first angle limiting plate arranged in the trench of the first frame and defining a plurality of slits, where the trench is arranged in a lengthwise direction of the first frame.

The trench of the first frame may pass through the first frame in a thickness direction of the first frame.

A thickness of the first frame may be greater than a thickness of the first angle limiting plate.

The first angle limiting plate may define a first slit extending from a central portion of the first angle limiting plate toward a side surface of the first angle limiting plate, and the plurality of slits may include the first slit.

The first angle limiting plate may define a second slit extending from an edge of a first side surface of the first angle limiting plate toward a central portion of the first angle limiting plate, and the plurality of slits may include the second slit.

The first angle limiting plate may further define a third slit extending from an edge of a second side surface of the first angle limiting plate toward the central portion of the first angle limiting plate, the second side surface may be opposite to the first side surface, and the plurality of slits may include the third slit.

At least one of the plurality of slits may pass through the first angle limiting plate in a direction that is diagonal with respect to a thickness direction of the first angle limiting plate.

The apparatus may further include: a second frame arranged on the evaporation source to face the first frame with the nozzle between the second frame and the first frame, where the second frame defining a trench therein; and a second angle limiting plate arranged in the trench of the second frame and defining another plurality of slits therein, where the trench of the second frame may be arranged in a lengthwise direction of the second frame.

The first and second angle limiting plates may be linear shaped in a certain direction, the evaporation source may be provided in plurality, and the plurality of the evaporation sources may be serially arranged in the lengthwise direction of the first frame and disposed between the first and second angle limiting plates.

The evaporation source may include a crucible arranged below the nozzle, a heat source arranged to be adjacent to the crucible, and a cover arranged on the crucible and the heat source and defining an opening overlapping the nozzle.

The nozzle and the cover may be arranged to be spaced apart from each other.

According to one or more embodiments, a method of manufacturing a display apparatus includes: preparing an object to be processed, preparing an evaporation source capable of storing a deposition material; heating the deposition material by using a heat source provided in the evaporation source; and depositing the heated deposition material on the object to be processed by spraying the heated deposition material toward the object to be processed, where a frame arranged on the evaporation source and defining a trench therein and an angle limiting plate arranged in the trench of the frame and defining a plurality of slits are used in the method.

In the depositing of the heated deposition material on the object to be processed by spraying the heated deposition material, a spraying angle of the heated deposition material may be limited by the angle limiting plate.

The angle limiting plate may define a first slit extending from a central portion of the angle limiting plate toward a side surface of the angle limiting plate, and the plurality of slits may include the first slit.

The angle limiting plate may define a second slit extending from an edge of a first side surface of the angle limiting plate toward a central portion of the angle limiting plate, and the plurality of slits may include the second slit.

The angle limiting plate may further define a third slit extending from an edge of a second side surface of the first angle limiting plate toward the central portion of the angle limiting plate, the second side surface may be opposite to the first side surface, and the plurality of slits may include the third slit.

The plurality of slits may disrupt heat transfer through the angle limiting plate.

At least one of the plurality of slits may pass through the angle limiting plate in a direction that is diagonal with respect to a thickness direction of the angle limiting plate.

In the depositing of the heated deposition material on the object to be processed by spraying the heated deposition material, at least a portion of the heated deposition material may not pass through the plurality of slits of the angle limiting plate.

The angle limiting plate may be linear shaped in a certain direction, and in the depositing of the heated deposition material on the object to be processed by spraying the heated deposition material, the object to be processed may be moved, with respect to the evaporation source, in the certain direction.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are schematic cross-sectional views of a portion of an apparatus for manufacturing a display apparatus, according to an embodiment;

FIG. 3 is an enlarged cross-sectional view of a portion of an apparatus for manufacturing a display apparatus, according to an embodiment;

FIG. 4 is a front view of a portion of an angle limiting plate according to an embodiment;

FIG. 5 is a perspective view of a portion of an angle limiting plate according to an embodiment;

FIG. 6 is a front view of a portion of an angle limiting plate according to another embodiment;

FIG. 7 is a front view of a portion of an angle limiting plate according to still another embodiment;

FIGS. 8A and 8B are enlarged cross-sectional views of a portion of an angle limiting plate according to an embodiment;

FIG. 9 is a schematic front view of a heat transfer path in an angle limiting plate according to an embodiment;

FIG. 10A is a schematic heat distribution diagram of an angle limiting plate and a frame in which a slit is not implemented, according to an embodiment;

FIG. 10B is a schematic heat distribution diagram of an angle limiting plate and a frame in which a slit is implemented, according to an embodiment;

FIG. 11 is a schematic plan view of a portion of an apparatus for manufacturing a display apparatus, according to an embodiment;

FIG. 12 is a schematic plan view of a display apparatus which may be manufactured by an apparatus for manufacturing a display apparatus, according to an embodiment; and

FIG. 13 is a schematic cross-sectional view of a portion of a display apparatus which may be manufactured by an apparatus for manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments thereof are shown by way of example in the drawings and will herein be described in detail. Effects and characteristics of the disclosure, and realizing methods thereof will become apparent by referring to the drawings and embodiments described in detail below. However, the disclosure is not limited to the embodiments disclosed hereinafter and may be realized in various forms.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

When a certain embodiment may be implemented differently, a specific process order may be performed differently from the described order. For example, two consecutively described processes may be performed substantially at the same time or performed in an order opposite to the described order.

In this specification, the expression “A and/or B” may indicate A, B, or A and B. Also, the expression “at least one of A and B” may indicate A, B, or A and B.

In the embodiments hereinafter, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Hereinafter, embodiments will be described in detail by referring to the accompanying drawings. In descriptions with reference to the drawings, the same reference numerals are given to elements that are the same or substantially the same and descriptions will not be repeated.

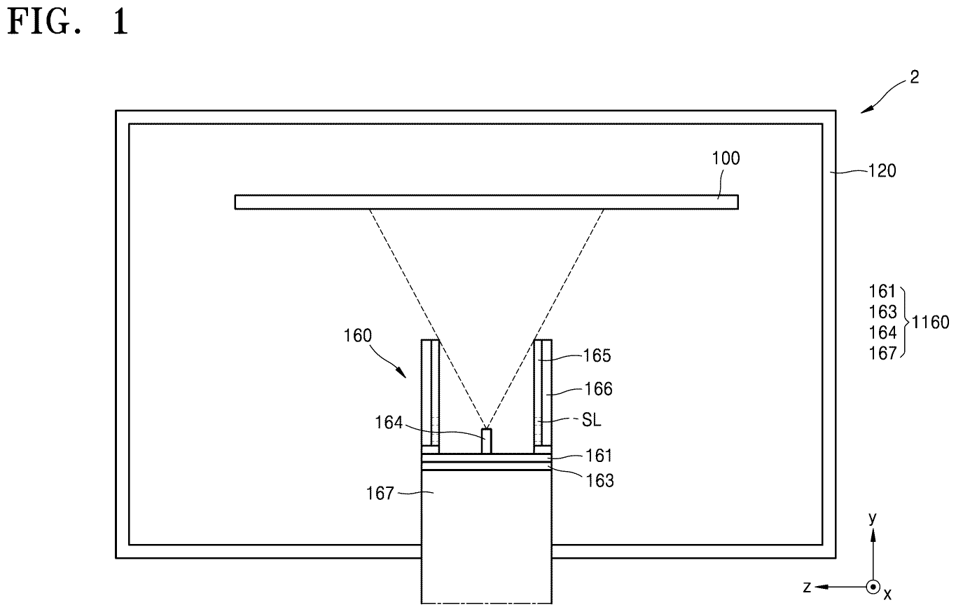

FIG. 1 is a schematic cross-sectional view of a portion of an apparatus 2 for manufacturing a display apparatus according to an embodiment.

Referring to FIG. 1, the apparatus 2 for manufacturing a display apparatus according to an embodiment may include a chamber 120 and a deposition source 160.

According to an embodiment, the apparatus 2 for manufacturing a display apparatus may perform a process of depositing (or growing) a thin film on a substrate 100 provided in the display apparatus 2.

Types of the deposition process performed by the apparatus 2 for manufacturing a display apparatus are not limited. In an embodiment, for example, the apparatus 2 for manufacturing a display apparatus may perform physical vapor deposition (“PVD”), such as heat deposition, vacuum deposition, ion plating, and sputtering. Also, types of the thin film formed by the deposition process performed by the apparatus 2 for manufacturing a display apparatus are not limited. In an embodiment, for example, an electrode layer, a metal layer, an inorganic insulating layer, an organic insulating layer, etc. of the display apparatus may be formed on the substrate 100, which is an “object to be processed” that is arranged in the chamber 120 of the apparatus 2 for manufacturing a display apparatus.

The chamber 120 may provide an inner space in which the deposition process may be performed. That is, the chamber 120 may be a reaction chamber including a predetermined reaction space. According to an embodiment, the inner space of the chamber 120 may be maintained as a low vacuum state or a high vacuum state.

A pumping portion (not shown) may be arranged on a side surface of the chamber 120. The pumping portion may discharge air inside the chamber 120 to the outside of the chamber 120, and thus, may maintain the inner space of the chamber 120 to be in a low or high vacuum state.

A deposition source 160 may be arranged on a side surface of the chamber 120 and may supply and inject a deposition material. The deposition source 160 may include an evaporation source 1160, an angle limiting plate 165 arranged above the evaporation source 1160, and a frame 166 arranged above the evaporation source 1160. After the deposition source 160 receives the deposition material from the outside or loads the deposition material, the deposition source 160 may be arranged in the chamber 120.

The deposition source 160 may include the evaporation source 1160 for storing and spraying the deposition material. The evaporation source 1160 may include a nozzle 164 for spraying a deposition material, a body 167 storing and/or heating the deposition material, a bracket 163 arranged above the body 167, and a base plate 161 arranged above the bracket 163.

According to an embodiment, the evaporation source 1160 may be used for thermal evaporation, which is a type of PVD. The evaporation source 1160 may evaporate and/or sublimate the deposition material by heating the deposition material through the body 167 and inject the deposition material by using the nozzle 164.

The deposition source 160 may include the angle limiting plate 165 and the frame 166 arranged above the evaporation source 1160. A portion of the frame 166 may be in direct contact with the base plate 161, and another portion of the frame 166 may protrude in a direction (for example, a +y direction). The angle limiting plate 165 may be adjacent to a side surface of the frame 166 and may be arranged on the frame 166.

The evaporation source 1160 may include a plurality of angle limiting plates 165 and a plurality of frames 166. The plurality of angle limiting plates 165 may be arranged to face each other with the nozzle 164 therebetween. The plurality of frames 166 may be arranged to face each other with the nozzle 164 therebetween. In an embodiment, for example, the plurality of angle limiting plates 165 and the plurality of frames 166 may be arranged in a +z direction with respect to the nozzle 164.

The angle limiting plate 165 may define a plurality of slits SL therein. In an embodiment, for example, the angle limiting plate 165 may define the plurality of slits SL passing through the angle limiting plate 165 in the +z direction.

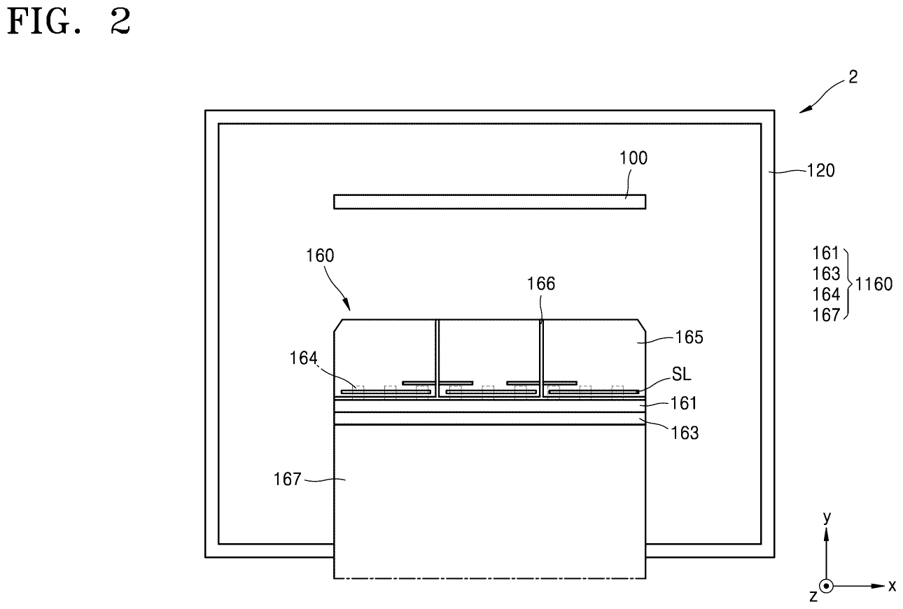

FIG. 2 is a schematic cross-sectional view of a portion of an apparatus for manufacturing a display apparatus, according to an embodiment. FIG. 2 is a schematic cross-sectional view cut by a plane (i.e., xy plane) perpendicular to a cutting plane (i.e., yz plane) used to make the cross-sectional view of FIG. 1. Hereinafter, the same aspects as the aspects described with reference to FIG. 1 are not repeatedly described, and aspects illustrated in FIG. 2 are mainly described.

Referring to FIG. 2, the evaporation source 1160 may include a plurality of nozzles 164 arranged in series in a certain direction. In an embodiment, for example, the evaporation source 1160 may include the plurality of nozzles 164 serially arranged in a ±x direction.

A portion of the frame 166 may be in direct contact with the base plate 161. The frame 166 may include a protrusion portion protruding in a direction (for example, a +y direction). In other words, the frame 166 may define a trench recessed in an opposite direction (for example, a −y direction).

Hereinafter, it is described that the frame 166 may include two protrusion portions (or three trenches). However, the disclosure is not limited thereto. According to another embodiment, the frame 166 may include three or more protrusion portions (or four or more trenches). The frame 166 may have a shape where several “T” shapes are connected in series. A lengthwise direction of the frame 166 may be x direction, while a lengthwise direction of each protrusion portion may be y direction.

The angle limiting plate 165 may be arranged between the protrusion portions of the frame 166. Alternatively, the angle limiting plate 165 may be arranged in the trenches of the frame 166. An upper surface of the angle limiting plate 165 and an upper surface of the frame 166 may be on the same plane.

The angle limiting plate 165 may define a plurality of slits SL therein. In an embodiment, for example, the angle limiting plate 165 may define the plurality of slits SL extending in the +x direction.

The plurality of slits SL may be arranged in a portion of the angle limiting plate 165. In other words, the plurality of slits SL may be arranged in a portion of the angle limiting plate 165, where the portion is adjacent to the base plate 161. Some of the plurality of slits SL may overlap the nozzle 164 in the cross-sectional view.

The slit SL may not be arranged at a surface edge of the angle limiting plate 165, where the surface edge is at an outermost portion of the base plate 161. That is because, if the slit SL is formed at a side surface edge of the angle limiting plate 165, where the side surface edge is not in contact with the frame 166, transformation (for example, flexure) of the angle limiting plate 165 may occur in a deposition process.

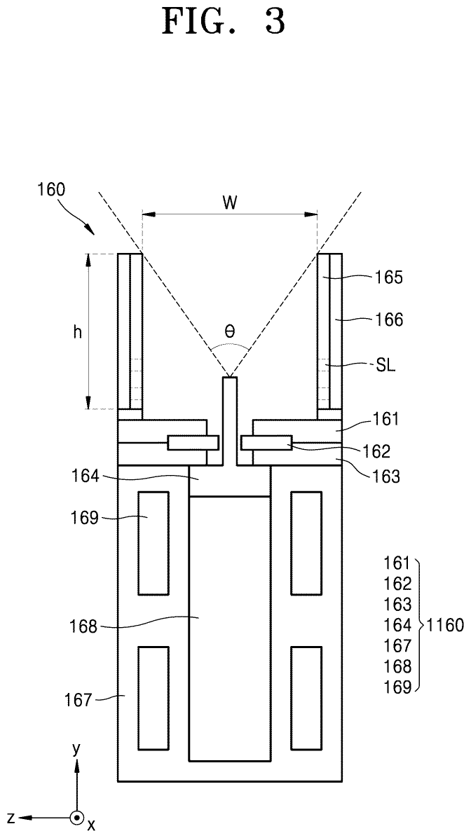

FIG. 3 is an enlarged cross-sectional view of a portion of an apparatus for manufacturing a display apparatus, according to an embodiment.

According to an embodiment, the cross-sectional view of FIG. 3 may show the enlarged deposition source 160 illustrated in FIGS. 1 and 2, according to an embodiment.

Referring to FIG. 3, the evaporation source 1160 may include the base plate 161, a reflector 162, the bracket 163, the nozzle 164, the body 167, a crucible 168, and a heat source 169.

A portion of the nozzle 164, the crucible 168, and the heat source 169 may be arranged in the body 167 of the evaporation source 1160.

The crucible 168 may provide a space for storing a deposition material. The deposition material may be heated and evaporated (or sublimated) in the crucible 168. Thus, the crucible 168 may include a material having low heat resistance for smooth heat transfer.

Although not shown in FIG. 3, the crucible 168 may continually receive the deposition material through an additional element. According to an embodiment, the crucible 168 may be connected to an additional hose (not shown) and may receive the deposition material from the outside.

The heat source 169 may be arranged to be adjacent to the crucible 168. The heat source 169 may be provided in plural. In an embodiment, for example, the plurality of heat sources 169 may be arranged to face each other with the crucible 168 therebetween or may be arranged to surround the crucible 168. FIG. 3 illustrates that a portion of the body 167 is arranged between the heat source 169 and the crucible 168. However, the disclosure is not limited thereto, and the heat source 169 and the crucible 168 may be in direct contact with each other.

The nozzle 164 may be in direct contact with an upper portion of the crucible 168 and may be arranged above the crucible 168. The nozzle 164 may inject the deposition material heated and evaporated in the crucible 168. A contact surface between the nozzle 164 and the crucible 168 may be sealed so that the deposition material is not leaked.

The bracket 163 may be arranged above the body 167 to cover a portion of an edge portion (or an edge) of the nozzle 164. The bracket 163 may connect the body 167 with the base plate 161 and may provide a space in which the reflector 162 may be arranged.

The base plate 161 may be arranged on the bracket 163 to overlap the bracket 163. The base plate 161 may provide a flat surface on which the angle limiting plate 165 and the frame 166 may be arranged.

The reflector 162 may be arranged between the bracket 163 and the base plate 161. The reflector 162 may prevent transfer of a portion of heat generated in the heat source 169 in a direction (for example, a +y direction).

The base plate 161, the reflector 162, and the bracket 163 may define an opening therein passing through each of the base plate 161, the reflector 162, and the bracket 163. Through the opening of the base plate 161, the reflector 162, and the bracket 163, a portion of the nozzle 164 may extend in a direction (for example, the +y direction), and the deposition material may be injected through the extending portion.

A side surface of the base plate 161, the reflector 162, and the bracket 163, where the side surface includes the opening, may be spaced apart from the nozzle 164. In an embodiment, for example, the side surface of the reflector 162 may be spaced apart from a side surface of the nozzle 164. Here, the base plate 161 may be referred to as a “cover”.

The deposition material in a high temperature gas state, which is heated and evaporated (or sublimated) in the crucible 168, may be present in the nozzle 164. The reflector 162 may prevent the transfer of heat generated in the heat source 169 to the outside, and thus, may maintain a lower temperature than the deposition material in the nozzle 164. If the nozzle 164 and the reflector 162 are in contact with each other, the temperature of the deposition material in the nozzle 164 may be decreased, and thus, the deposition material may be condensed, which may cause clogging of the nozzle 164. When the side surface of the nozzle 164 and the side surface of the reflector 162 are spaced apart from each other, the clogging of the nozzle 164 may be prevented.

The angle limiting plate 165 and the frame 166 may be arranged on the base plate 161. The shapes of the angle limiting plate 165 and the frame 166 are the same as described above with reference to FIGS. 1 and 2.

The angle limiting plate 165 may adjust a spraying angle θ of the deposition material injected by the nozzle 164. If the angle limiting plate 165 is not arranged, the deposition material may have a greater spraying angle than when the angle limiting plate 165 is arranged. In this case, a portion of the injected deposition material may be disposed in another space in the chamber, rather than a target object to be processed (e.g., the substrate 100). In order to improve the accuracy of deposition and minimize the waste of disposal of the deposition material in a different space from the object to be processed, the angle limiting plate 165 may be used. During the deposition process, the target object to be processed may move, with respect to the evaporation source 1160, in z direction. As a height h of the angle limiting plate 165 increases, the spraying angle θ of the deposition material may decrease. As a gap w between the angle limiting plates 165 decreases, the spraying angle θ of the deposition material may decrease.

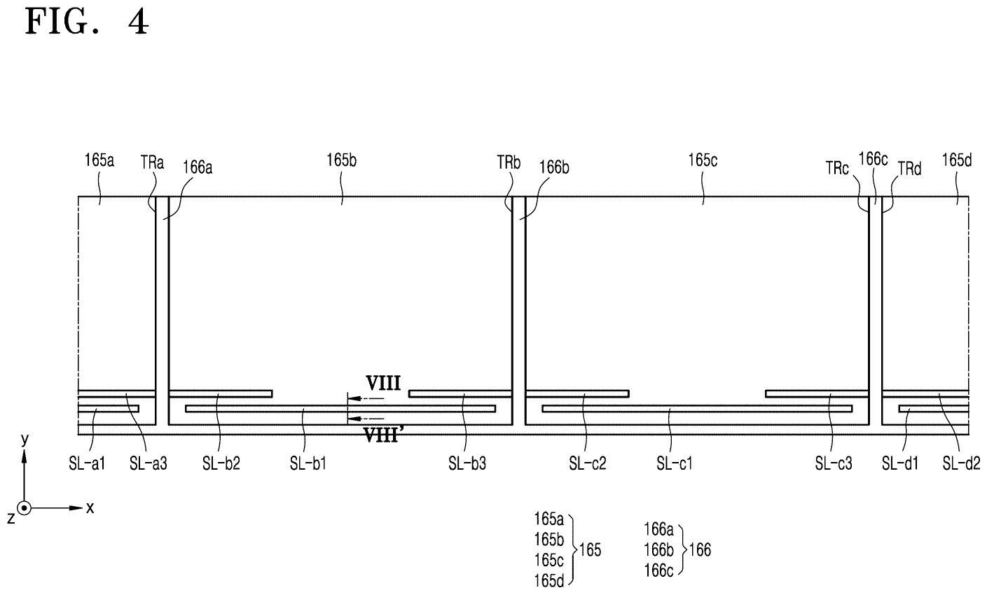

FIG. 4 is a front view of a portion of an angle limiting plate according to an embodiment.

Referring to FIG. 4, the frame 166 may include a plurality of protrusion portions. In an embodiment, for example, the frame 166 may include first to third protrusion portions 16a, 166b, and 166c.

In other words, the frame 166 may define a plurality of trenches therein recessed in a −y direction. In an embodiment, for example, the frame 166 may define first to fourth trenches TRa, TRb, TRc, and TRd therein recessed in the −y direction.

The angle limiting plate 165 may be arranged between the protrusion portions of the frame 166. According to an embodiment, a first angle limiting plate 165a may be arranged in a direction (for example, a-x direction) with respect to the first protrusion portion 166a. A second angle limiting plate 165b may be arranged between the first protrusion portion 166a and the second protrusion portion 166b. A third angle limiting plate 165c may be arranged between the second protrusion portion 166b and the third protrusion portion 166c. A fourth angle limiting plate 166d may be arranged in a direction (for example, a +x direction) with respect to the third protrusion portion 166c.

In other words, the angle limiting plate 165 may be arranged in the trench of the frame 166. According to an embodiment, the first angle limiting plate 165a may be arranged in the first trench TRa. The second angle limiting plate 165b may be arranged in the second trench TRb. The third angle limiting plate 165c may be arranged in the third trench TRc. The fourth angle limiting plate 165d may be arranged in the fourth trench TRd.

A length of the protrusion portion of the frame 166 in a certain direction and a length of the angle limiting plate 165 in the certain direction may be substantially the same as each other. In an embodiment, for example, lengths of the first to third protrusion portions 166a, 166b, and 166c in the ty direction may each be substantially the same as each of lengths of the first to fourth angle limiting plates 165a, 165b, 165c, and 165d in the ±y direction.

A length of the trench of the frame 166 in a certain direction and a length of the angle limiting plate 165 in the certain direction may be substantially the same as each other. In an embodiment, for example, lengths of the first to fourth trenches TRa, TRb, TRc, and TRd in the ty direction may each be substantially the same as each of lengths of the first to fourth angle limiting plates 165a, 165b, 165c, and 165d in the ty direction. Lengths of the first to fourth trenches TRa, TRb, TRc, and TRd in the ±x direction may each be substantially the same as each of lengths of the first to fourth angle limiting plates 165a, 165b, 165c, and 165d in the ±x direction.

In other words, upper surfaces (in y direction) of the first to third protrusion portions 166a, 166b, and 166c and upper surfaces of the first to fourth angle limiting plates 165a, 165b, 165c, and 165d may be on the same plane.

The angle limiting plate 165 may define a plurality of slits therein. In an embodiment, for example, the first angle limiting plate 165a may define a 1-1^{st} slit SL-a1, a 1-2^{nd} slit (not shown), and a 1-3^{rd} slit SL-a3 therein. The second angle limiting plate 165b may define a 2-1^{st} slit SL-b1, a 2-2^{nd} slit SL-b2, and a 2-3^{rd} slit SL-b3 therein. The third angle limiting plate 165c may define a 3-1^{st} slit SL-c1, a 3-2^{nd} slit SL-c2, and a 3-3^{rd} slit SL-c3 therein. The fourth angle limiting plate 165d may define a 4-1^{st} slit SL-d1, a 4-2^{nd} slit SL-d2, and a 4-3^{rd} slit (not shown) therein.

Some of the slits of the angle limiting plate 165 may extend in a predetermined direction of the angle limiting plate 165 from a central portion of the angle limiting plate 165. In an embodiment, for example, some of the slits of the angle limiting plate 165 may extend in the ±x direction from the central portion of the angle limiting plate 165 with respect to an x axis.

According to an embodiment, the 1-1^{st} slit SL-a1 may extend in the ±x direction from the central portion of the first angle limiting plate 165a with respect to the x axis.

The 2-1^{st} slit SL-b1 may extend in the ±x direction from the central portion of the second angle limiting plate 165b with respect to the x axis.

The 3-1^{st} slit SL-c1 may extend in the ±x direction from the central portion of the third angle limiting plate 165c with respect to the x axis.

The 4-1^{st} slit SL-d1 may extend in the ±x direction from the central portion of the fourth angle limiting plate 165d with respect to the x axis.

The 1-1^{st}, 2-1^{st}, 3-1^{st}, and 4-1^{st} slits SL-a1, SL-b1, SL-c1, and SL-d1 may not pass through the first to fourth angle limiting plates 165a, 165b, 165c, and 165d in an x-axis direction. In an embodiment, for example, surfaces of the 1-1^{st}, 2-1^{st}, 3-1^{st}, and 4-1^{st} slits SL-a1, SL-b1, SL-c1, and SL-d1 and surfaces of the first to third protrusion portions 166a, 166b, and 166c may be spaced apart from each other.

According to an embodiment, a side surface of the 1-1^{st} slit SL-a1 facing toward the first protrusion portion 166a (or in the +x direction) may be spaced apart from a side surface of the first protrusion portion 166a facing toward the 1-1^{st} slit SL-a1 (or in the −x direction).

A side surface of the 2-1^{st} slit SL-b1 facing toward the first protrusion portion 166a (or in the −x direction) may be spaced apart from a side surface of the first protrusion portion 166a facing toward the 2-1^{st} slit SL-b1 (or in the +x direction).

A side surface of the 2-1^{st} slit SL-b1 facing toward the second protrusion portion 166b (or in the +x direction) may be spaced apart from a side surface of the second protrusion portion 166b facing toward the 2-1^{st} slit SL-b1 (or in the −x direction).

A side surface of the 3-1^{st} slit SL-c1 facing toward the second protrusion portion 166b (or in the −x direction) may be spaced apart from a side surface of the second protrusion portion 166b facing toward the 3-1^{st} slit SL-c1 (or in the +x direction).

A side surface of the 3-1^{st} slit SL-c1 facing toward the third protrusion portion 166c (or in the +x direction) may be spaced apart from a side surface of the third protrusion portion 166c facing toward the 3-1^{st} slit SL-c1 (or in the −x direction).

A side surface of the 4-1^{st} slit SL-d1 facing toward the third protrusion portion 166c (or in the −x direction) may be spaced apart from a side surface of the third protrusion portion 166c facing toward the 4-1^{st} slit SL-d1 (or in the +x direction).

The others of the slits of the angle limiting plate 165 may extend from an edge of a side surface of the angle limiting plate 165 toward the central portion of the angle limiting plate 165. In an embodiment, for example, the others of the slits of the angle limiting plate 165 may extend from an edge of a side surface of the angle limiting plate 165 in the −x direction or the +x direction toward the central portion of the angle limiting plate 165.

According to an embodiment, the 2-2^{nd} slit SL-b2 may extend from a side surface of the second angle limiting plate 165b in the −x direction toward the central portion of the second angle limiting plate 165b (or in the +x direction).

The 3-2^{nd} slit SL-c2 may extend from a side surface of the third angle limiting plate 165c in the −x direction toward the central portion of the third angle limiting plate 165c (or in the +x direction).

The 4-2^{nd} slit SL-d2 may extend from a side surface of the fourth angle limiting plate 165d in the −x direction toward the central portion of the fourth angle limiting plate 165d (or in the +x direction).

The 1-3^{rd} slit SL-a3 may extend from a side surface of the first angle limiting plate 165a in the +x direction toward the central portion of the first angle limiting plate 165a (or in the −x direction).

The 2-3^{rd} slit SL-b3 may extend from a side surface of the second angle limiting plate 165b in the +x direction toward the central portion of the second angle limiting plate 165b (or in the −x direction).

The 3-3^{rd} slit SL-c3 may extend from a side surface of the third angle limiting plate 165c in the +x direction toward the central portion of the third angle limiting plate 165c (or in the −x direction).

The 1-1^{st}, 2-1^{st}, 3-1^{st}, and 4-1^{st} slits SL-a1, SL-b1, SL-c1, and SL-d1 may partially overlap the 2-2^{nd}, 3-2^{nd}, and 4-2^{nd} slits SL-b2, SL-c2, and SL-d2 and the 1-3^{rd}, 2-3^{rd}, and 3-3^{rd} slits SL-a3, SL-b3, and SL-c3 in a view from the y direction.

According to an embodiment, the 1-1^{st} slit SL-a1 may partially overlap the 1-3^{rd} slit SL-a3. The 2-1^{st} slit SL-b1 may partially overlap the 2-2^{nd} slit SL-b2 and the 2-3^{rd} slit SL-b3 in a view from the y direction. The 3-1^{st} slit SL-c1 may partially overlap the 3-2^{nd} slit SL-c2 and the 3-3^{rd} slit SL-c3. The 4-1^{st} slit SL-d1 may partially overlap the 4-2^{nd} slit SL-d2 in a view from the y direction.

Because the 1-1^{st}, 2-1^{st}, 3-1^{st}, and 4-1^{st} slits SL-a1, SL-b1, SL-c1, and SL-d1 partially overlap the 2-2^{nd}, 3-2^{nd}, and 4-2^{nd} slits SL-b2, SL-c2, and SL-d2 and the 1-3^{rd}, 2-3^{rd}, and 3-3^{rd} slits SL-a3, SL-b3, and SL-c3 in a view from the y direction, a portion of the angle limiting plate 165, where the portion is around the slits, may approximately have a zig-zag shape.

In an embodiment, for example, a portion of the first angle limiting plate 165a, where the portion is around the 1-1^{st} and 1-3^{rd} slits SL-a1 and SL-a3, may approximately have a zig-zag shape.

A portion of the second angle limiting plate 165b, where the portion is around the 2-1^{st} to 2-3^{rd} slits SL-b1, SL-b2, and SL-b3, may approximately have a zig-zag shape.

A portion of the third angle limiting plate 165c, where the portion is around the 3-1^{st} to 3-3^{rd} slits SL-c1, SL-c2, and SL-c3, may approximately have a zig-zag shape.

A portion of the fourth angle limiting plate 165d, where the portion is around the 4-1^{st} and 4-2^{nd} slits SL-d1 and SL-d2, may approximately have a zig-zag shape.

The slits of the angle limiting plate 165 may be arranged in a portion of the angle limiting plate 165. In an embodiment, for example, the slits of the angle limiting plate 165 may be sequentially arranged in the +y direction from a lower portion (or a portion in the −y direction) of the angle limiting plate 165.

According to an embodiment, the 1-1^{st} slit SL-a1 and the 1-3^{rd} slit SL-a3 may be sequentially arranged in the ty direction from a lower portion (or a portion in the −y direction) of the first angle limiting plate 165a.

The 2-1^{st} to 2-3^{rd} slits SL-b1 to SL-b3 may be sequentially arranged in the +y direction from a lower portion (or a portion in the −y direction) of the second angle limiting plate 165b.

The 3-1^{st} to 3-3^{rd} slits SL-c1 to SL-c3 may be sequentially arranged in the +y direction from below (or a portion of the −y direction) the third angle limiting plate 165c.

The 4-1^{st} and 4-2^{nd} slits SL-d1 and SL-d2 may be sequentially arranged in the +y direction from a lower portion (or a portion in the −y direction) of the fourth angle limiting plate 165d.

FIG. 4 illustrates that the 1-1^{st}, 2-1^{st}, 3-1^{st}, and 4-1^{st} slits SL-a1, SL-b1, SL-c1, and SL-d1 are arranged in the same position with respect to the ty direction, and the 1-3^{rd} slit SL-a3, the 2-2^{nd} and 2-3^{rd} slits SL-b2 and SL-b3, the 3-2^{nd} and 3-3^{rd} slits SL-c2 and SL-c3, and the 4-2^{nd} slit SL-d2 are arranged in the same position with respect to the ty direction. However, the disclosure is not limited thereto. According to another embodiment, the 1-1^{st}, 2-1^{st}, 3-1^{st}, and 4-1^{st} slits SL-a1, SL-b1, SL-c1, and SL-d1 may be arranged in different positions with respect to the ty direction, and the 1-3^{rd} slit SL-a3, the 2-2^{nd} and 2-3^{rd} slits SL-b2 and SL-b3, the 3-2^{nd} and 3-3^{rd} slits SL-c2 and SL-c3, and the 4-2^{nd} slit SL-d2 may be arranged in different positions with respect to the ty direction.

FIG. 4 illustrates that the slits approximately have a quadrangular shape having an angled edge. However, the disclosure is not limited thereto. According to another embodiment, the slits may approximately have a quadrangular shape having a round edge.

FIG. 4 illustrates that each of the first to fourth angle limiting plates 165a, 165b, 165c, and 165d may define two or three slits therein. However, the disclosure is not limited thereto. According to another embodiment, the first to fourth angle limiting plates 165a to 165d may further define a plurality of slits having substantially the same characteristics as the slits illustrated in FIG. 4.

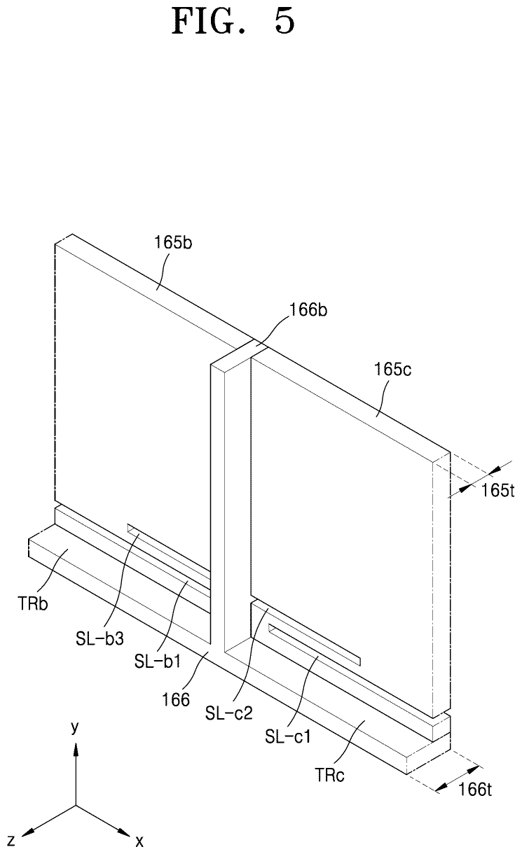

FIG. 5 is a perspective view of a portion of an angle limiting plate according to an embodiment.

Hereinafter, by referring to FIG. 5, aspects of the frame 166 and the angle limiting plate 165, which are not described above, will be mainly described.

The frame 166 may include the second protrusion portion 166b, the second trench TRb, and the third trench TRc. The second trench TRb may be arranged in a −x direction with respect to the second protrusion portion 166b, and the third trench TRc may be arranged in a +x direction with respect to the second protrusion portion 166b.

The second and third trenches TRb and TRc may extend in the ±x direction.

The second and third trenches TRb and TRc may be blind holes not passing through the frame 166 in a ±y direction.

The second and third trenches TRb and TRc may be penetration holes passing through the frame 166 in a ±z direction, which is a thickness direction of the frame 166.

A thickness 166t of the frame 166 may be greater than a thickness 165t of the second and third angle limiting plates 165b and 165c. By having the thickness 166t that is greater than the thickness 165t of the second and third angle limiting plates 165b and 165c, the frame 166 may function as a support shaft preventing transformation of the second and third angle limiting plates 165b and 165c. Here, the thicknesses 166t and 165t are measured in the z direction.

FIG. 5 illustrates that the second and third angle limiting plates 165b and 165c are arranged at an end of the frame 166 in a −z direction. However, the disclosure is not limited thereto. According to another embodiment, the second and third angle limiting plates 165b and 165c may be arranged at a central portion of the frame 166 with respect to the ±z direction or may be arranged at an end of the frame 166 in a +z direction. According to another embodiment, the second angle limiting plate 165b may be arranged at the end (the same position as illustrated in FIG. 5) of the frame 166 in the −z direction, and the third angle limiting plate 165c may be arranged at the end of the frame 166 in the +z direction.

The aspects of the frame 166 and the angle limiting plate 165 described above with reference to FIG. 5 are not limited to the frame 166 and the second and third angle limiting plates 165b and 165c illustrated in FIG. 5 and may be generally applied to the frame and angle limiting plate according to various embodiments.

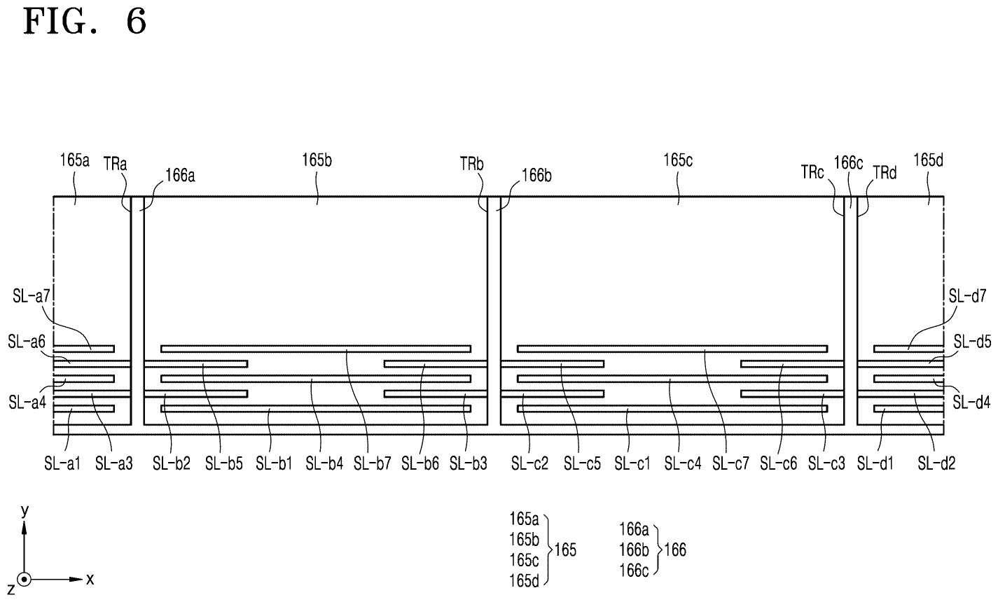

FIG. 6 is a front view of a portion of the angle limiting plate 165 according to another embodiment.

Referring to FIG. 6, the angle limiting plate 165 may define a 1-1^{st} slit SL-a1, a 1-3^{rd} slit SL-a3, a 1-4th slit SL-a4, a 1-6th slit SL-a6, a 1-7^{th} slit SL-a7, 2-1^{st} to 2-7^{th} slits SL-b1 to SL-b7, 3-1^{st} to 3-7^{th} slits SL-c1 to SL-c7, a 4-1^{st} slit SL-d1, a 4-2^{nd} slit SL-d2, a 4-4^{th} slit SL-d4, a 4-5^{th} slit SL-d5, and a 4-7^{th} slit SL-d7 therein.

Aspects of the 1-1^{st} and 1-3^{rd} slits SL-a1 and SL-a3, the 2-1^{st} to 2-3^{rd} slits SL-b1 to SL-b3, the 3-1^{st} to 3-3^{rd} slits SL-c1 to SL-c3, and the 4-1^{st} and 4-2^{nd} slits SL-d1 and SL-d2 are described above with reference to FIG. 4, and thus, will not be repeatedly described, and hereinafter, different aspects will be mainly described.

Aspects of the 1-4^{th}, 2-4^{th}, 3-4^{th}, and 4-4^{th} slits SL-a4, SL-b4, SL-c4, and SL-d4 and the 1-7^{th}, 2-7^{th}, 3-7^{th}, and 4-7^{th} slits SL-a7 to SL-d7 may be substantially the same as the aspects of the 1-1^{st}, 2-1^{st}, 3-1^{st}, and 4-1^{st} slits SL-a1, SL-b1, SL-c1, and SL-d1.

According to an embodiment, the 1-4^{th} slit SL-a4 and the 1-7^{th} slit SL-a7 may extend in a +x direction from a central portion of the first angle limiting plate 165a with respect to an x-axis.

The 2-4^{th} slit SL-b4 and the 2-7^{th} slit SL-b7 may extend in the ±x direction from a central portion of the second angle limiting plate 165b with respect to the x-axis.

The 3-4^{th} slit SL-c4 and the 3-7^{th} slit SL-c7 may extend in the ±x direction from a central portion of the third angle limiting plate 165c with respect to the x-axis.

The 4-4^{th} slit SL-d4 and the 4-7^{th} slit SL-d7 may extend in the ±x direction from a central portion of the fourth angle limiting plate 165d with respect to the x-axis.

The 1-4^{th}, 2-4^{th}, 3-4^{th}, and 4-4^{th} slits SL-a4, SL-b4, SL-c4, and SL-d4 and the 1-7^{th}, 2-7^{th}, 3-7^{th} and 4-7^{th} slits SL-a7, SL-b7, SL-c7, and SL-d7 may not pass through the first to fourth angle limiting plates 165a to 165d in an x-axis direction. In an embodiment, for example, surfaces of the 1-4^{th}, 2-4^{th}, 3-4^{th}, and 4-4^{th} slits SL-a4, SL-b4, SL-c4, and SL-d4 and the 1-7^{th}, 2-7^{th}, 3-7^{th}, and 4-7^{th} slits SL-a7, SL-b7, SL-c7, and SL-d7 may be spaced apart from surfaces of the first to third protrusion portions 166a to 166c.

According to an embodiment, a surface of the 1-4^{th} slit SL-a4 toward the first protrusion portion 166a (or in a +x direction) may be spaced apart from a surface of the first protrusion portion 166a toward the 1-4^{th} slit SL-a4 (or in a −x direction).

A surface of the 1-7^{th} slit SL-a7 toward the first protrusion portion 166a (or in the +x direction) may be spaced apart from a surface of the first protrusion portion 166a toward the 1-7^{th} slit SL-a7 (or in the −x direction).

A surface of the 2-4^{th} slit SL-b4 toward the first protrusion portion 166a (or in the −x direction) may be spaced apart from a surface of the first protrusion portion 166a toward the 2-4^{th} slit SL-b4 (or in the +x direction).

A surface of the 2-7^{th} slit SL-b7 toward the first protrusion portion 166a (or in the −x direction) may be spaced apart from a surface of the first protrusion portion 166a toward the 2-7^{th} slit SL-b7 (or in the +x direction).

A surface of the 2-4^{th} slit SL-b4 toward the second protrusion portion 166b (or in the +x direction) may be spaced apart from a surface of the second protrusion portion 166b toward the 2-4^{th} slit SL-b4 (or in the −x direction).

A surface of the 2-7^{th} slit SL-b7 toward the second protrusion portion 166b (or in the +x direction) may be spaced apart from a surface of the second protrusion portion 166b toward the 2-7^{th} slit SL-b7 (or in then −x direction).

A surface of the 3-4^{th} slit SL-c4 toward the second protrusion portion 166b (or in the −x direction) may be spaced apart from a surface of the second protrusion portion 166b toward the 3-4^{th} slit SL-c4 (or in the +x direction).

A surface of the 3-7^{th} slit SL-c7 toward the second protrusion portion 166b (or in the −x direction) may be spaced apart from a surface of the second protrusion portion 166b toward the 3-7^{th} slit SL-c7 (or in the +x direction).

A surface of the 3-4^{th} slit SL-c4 toward the third protrusion portion 166c (or in the +x direction) may be spaced apart from a surface of the third protrusion portion 166c toward the 3-4^{th} slit SL-c4 (or in the −x direction).

A surface of the 3-7^{th} slit SL-c7 toward the third protrusion portion 166c (or in the +x direction) may be spaced apart from a surface of the third protrusion portion 166c toward the 3-7^{th} slit SL-c7 (or in the −x direction).

A surface of the 4-4^{th} slit SL-d4 toward the third protrusion portion 166c (or in the −x direction) may be spaced apart from a surface of the third protrusion portion 166c toward the 4-4^{th} slit SL-d4 (or in the +x direction).

A surface of the 4-7^{th} slit SL-d7 toward the third protrusion portion 166c (or in the −x direction) may be spaced apart from a surface of the third protrusion portion 166c toward the 4-7^{th} slit SL-d7 (or in the +x direction).

Aspects of the 2-5^{th}, 3-5^{th}, and 4-5^{th} slits SL-b5, SL-c5, and SL-d5 may be substantially the same as the aspects of the 2-2^{nd}, 3-2^{nd}, and 4-2^{nd} slits SL-b2, SL-c2, and SL-d2.

According to an embodiment, the 2-5^{th} slit SL-b5 may extend from a surface of the second angle limiting plate 165b in the −x direction toward a central portion of the second angle limiting plate 165b (or in the +x direction).

The 3-5^{th} slit SL-c5 may extend from a surface of the third angle limiting plate 165c in the −x direction toward a central portion of the third angle limiting plate 165c (or in the +x direction).

The 4-5^{th} slit SL-d5 may extend from a surface of the fourth angle limiting plate 165d in the −x direction toward a central portion of the fourth angle limiting plate 165d (or in the +x direction).

Aspects of the 1-6^{th}, 2-6^{th}, and 3-6^{th} slits SL-a6, SL-b6, and SL-c6 may be substantially the same as the aspects of the 1-3^{rd}, 2-3^{rd} and 3-3^{rd} slits SL-a3, SL-b3, and SL-c3.

According to an embodiment, the 1-6^{th} slit SL-a6 may extend from a surface of the first angle limiting plate 165a in the +x direction toward a central portion of the first angle limiting plate 165a (or in the −x direction).

The 2-6^{th} slit SL-b6 may extend from a surface of the second angle limiting plate 165b in the +x direction toward a central portion of the second angle limiting plate 165b (or in the −x direction).

The 3-6^{th} slit SL-c6 may extend from a surface of the third angle limiting plate 165c in the +x direction toward a central portion of the third angle limiting plate 165c (or in the −x direction).

The 1-4^{th} and 1-7^{th} slits SL-a4 and SL-a7 may partially overlap the 1-6^{th} slit SL-a6.

The 2-4^{th} and 2-7^{th} slits SL-b4 and SL-b7 may partially overlap the 2-5^{th} and 2-6^{th} slits SL-b5 and SL-b6.

The 3-4^{th} and 3-7^{th} slits SL-c4 and SL-c7 may partially overlap the 3-5^{th} and 3-6^{th} slits SL-c5 and SL-c6.

The 4-4^{th} and 4-7^{th} slits SL-d4 and SL-d7 may partially overlap the 4-5^{th} slit SL-d5.

Because some of the 1-4^{th}, 1-6^{th}, and 1-7^{th} slits SL-a4, SL-a6, and SL-a7, the 2-4^{th} to 2-7^{th} slits SL-b4 to SL-b7, the 3-4^{th} to 3-7^{th} slits SL-c4 to SL-c7, and the 4-4^{th}, 4-5^{th}, and 4-7^{th} slits SL-d4, SL-d5, and SL-d7 may overlap each other, the zigzag shape of the angle limiting plate 165 illustrated in FIG. 4 may extend in a +y direction.

In an embodiment, for example, a portion of the first angle limiting plate 165a, where the portion is around the 1-1^{st}, 1-3^{rd}, 1-4^{th}, 1-6^{th}, and 1-7^{th} slits SL-a1, SL-a3, SL-a4, SL-a6, and SL-a7, may approximately have a zigzag shape.

A portion of the second angle limiting plate 165b, where the portion is around the 2-1^{st} to 2-7^{th} slits SL-b1 to SL-b7, may approximately have a zigzag shape.

A portion of the third angle limiting plate 165c, where the portion is around the 3-1^{st} to 3-7^{th} slits SL-c1 to SL-c7, may approximately have a zigzag shape.

A portion of the fourth angle limiting plate 165d, where the portion is around the 4-1^{st}, 4-2^{nd}, 4-4^{th}, 4-5^{th}, and 4-7^{th} slits SL-d1, SL-d2, SL-d4, SL-d5, and SL-d7, may approximately have a zigzag shape.

Aspects not described above about the slits of the angle limiting plate 165 may be the same as described above with reference to FIGS. 4 and 5.

FIG. 6 illustrates that each of the first to fourth angle limiting plates 165a, 165b, 165c, and 165d may define five or seven slits therein. However, the disclosure is not limited thereto. According to another embodiment, the first to fourth angle limiting plates 165a to 165d may further define a plurality of slits having substantially the same characteristics as the slits illustrated in FIG. 6.

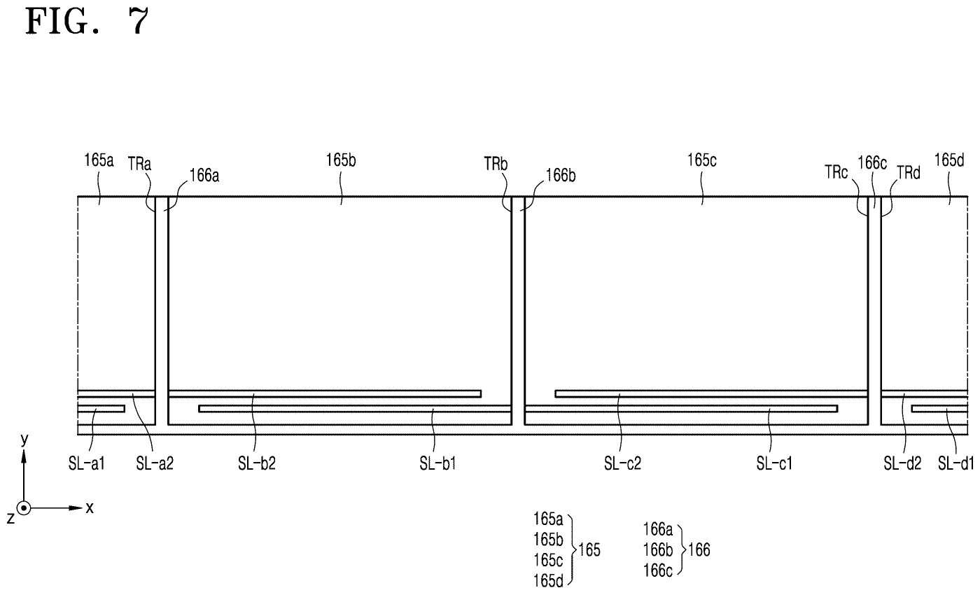

FIG. 7 is a front view of a portion of the angle limiting plate 165 according to still another embodiment.

Referring to FIG. 7, the angle limiting plate 165 may not include a slit extending from a central portion of the angle limiting plate 165 toward a side surface of the angle limiting plate 165.

The angle limiting plate 165 may define a slit extending from a surface of the angle limiting plate 165 toward an opposite surface of the angle limiting plate 165. In an embodiment, for example, the angle limiting plate 165 may define a slit extending from a surface of the angle limiting plate 165 in a +x direction toward a surface of the angle limiting plate 165 in a-x direction.

According to an embodiment, the angle limiting plate 165 may include the first to fourth angle limiting plates 165a to 165d. The first angle limiting plate 165a may define a 1-1^{st} slit SL-a1 and a 1-2^{nd} slit SL-a2. The second angle limiting plate 165b may define a 2-1^{st} slit SL-b1 and a 2-2^{nd} slit SL-b2. The third angle limiting plate 165c may define a 3-1^{st} slit SL-c1 and a 3-2^{nd} slit SL-c2. The fourth angle limiting plate 165d may define a 4-1^{st} slit SL-d1 and a 4-2^{nd} slit SL-d2.

The 1-1^{st} slit SL-a1 may extend in the +x direction from a surface of the first angle limiting plate 165a in the −x direction. A surface of the 1-1^{st} slit SL-a1 toward the first protrusion portion 166a (or in the +x direction) may be spaced apart from a surface of the first protrusion portion 166a toward the 1-1^{st} slit SL-a1 (or in the −x direction).

The 1-2^{nd} slit SL-a2 may extend in the −x direction from a surface of the first angle limiting plate 165a in the +x direction.

The 2-1^{st} slit SL-b1 may extend in the −x direction from a surface of the second angle limiting plate 165b in the +x direction. A surface of the 2-1^{st} slit SL-b1 toward the first protrusion portion 166a (or in the −x direction) may be spaced apart from a surface of the first protrusion portion 166a toward the 2-1^{st} slit SL-b1 (or in the +x direction).

The 2-2^{nd} slit SL-b2 may extend in the +x direction from a surface of the second angle limiting plate 165b in the −x direction. A surface of the 2-2^{nd} slit SL-b2 toward the second protrusion portion 166b (or in the +x direction) may be spaced apart from a surface of the second protrusion portion 166b toward the 2-2^{nd} slit SL-b2 (or in the −x direction).

The 3-1^{st} slit SL-c1 may extend in the ±x direction from a surface of the third angle limiting plate 165c in the −x direction. A surface of the 3-1^{st} slit SL-c1 toward the third protrusion portion 166c (or in the +x direction) may be spaced apart from a surface of the third protrusion portion 166c toward the 3-1^{st} slit SL-c1 (or in the −x direction).

The 3-2^{nd} slit SL-c2 may extend in the −x direction from a surface of the third angle limiting plate 165c in the +x direction. A surface of the 3-2^{nd} slit SL-c2 toward the second protrusion portion 166b (or in the −x direction) may be spaced apart from a surface of the second protrusion portion 166b toward the 3-2^{nd} slit SL-c2 (or in the +x direction).

The 4-1^{st} slit SL-d1 may extend in the −x direction from a surface of the fourth angle limiting plate 165d in the +x direction. A surface of the 4-1^{st} slit SL-d1 toward the third protrusion portion 166c (or in the −x direction) may be spaced apart from a surface of the third protrusion portion 166c toward the 4-1^{st} slit SL-d1 (or in the +x direction).

The 4-2^{nd} slit SL-d2 may extend in the +x direction from a surface of the fourth angle limiting plate 165d in the −x direction.

The 1-1^{st}, 2-1^{st}, 3-1^{st}, and 4-1^{st} slits SL-a1, SL-b1, SL-c1, and SL-d1 may partially overlap the 1-2^{nd}, 2-2^{nd}, 3-2^{nd}, and 4-2^{nd} slits SL-a2, SL-b2, SL-c2, and SL-d2, respectively.

According to an embodiment, the 1-1^{st} slit SL-a1 may partially overlap the 1-2^{nd} slit SL-a2. The 2-1^{st} slit SL-b1 may partially overlap the 2-2^{nd} slit SL-b2. The 3-1^{st} slit SL-c1 may partially overlap the 3-2^{nd} slit SL-c2. The 4-1^{st} slit SL-d1 may partially overlap the 4-2^{nd} slit SL-d2.

Because the 1-1^{st}, 2-1^{st}, 3-1^{st}, and 4-1^{st} slits SL-a1, SL-b1, SL-c1, and SL-d1 may partially overlap the 1-2^{nd}, 2-2^{nd}, 3-2^{nd}, and 4-2^{nd} slits SL-a2, SL-b2, SL-c2, and SL-d2, respectively, a portion of the angle limiting plate 165, where the portion is around the slit, may approximately have a zigzag shape.

In an embodiment, for example, a portion of the first angle limiting plate 165a, where the portion is around the 1-1^{st} and 1-2^{nd} slits SL-a1 and SL-a2, may approximately have a zig-zag shape.

A portion of the second angle limiting plate 165b, where the portion is around the 2-1^{st} and 2-2^{nd} slits SL-b1 and SL-b2, may approximately have a zigzag shape.

A portion of the third angle limiting plate 165c, where the portion is around the 3-1^{st} and 3-2^{nd} slits SL-c1 and SL-c2, may approximately have a zigzag shape.

A portion of the fourth angle limiting plate 165d, where the portion is around the 4-1^{st} and 4-2^{nd} slits SL-d1 and SL-d3, may approximately have a zigzag shape.

The slits of the angle limiting plate 165 may be arranged in a portion of the angle limiting plate 165. In an embodiment, for example, the slits of the angle limiting plate 165 may be sequentially arranged in a +y direction from a lower portion (or a portion in a −y direction) of the angle limiting plate 165.

According to an embodiment, the 1-1^{st} slit SL-a1 and the 1-2^{nd} slit SL-a2 may be sequentially arranged in the ty direction from a lower portion (or a portion in the −y direction) of the first angle limiting plate 165a.

The 2-1^{st} and 2-2^{nd} slits SL-b1 and SL-b2 may be sequentially arranged in the +y direction from a lower portion (or a portion in the −y direction) of the second angle limiting plate 165b.

The 3-1^{st} and 3-2^{nd} slits SL-c1 and SL-c2 may be sequentially arranged in the +y direction from a lower portion (or a portion in the −y direction) of the third angle limiting plate 165c.

The 4-1^{st} and 4-2^{nd} slits SL-d1 and SL-d2 may be sequentially arranged in the +y direction from a lower portion (or a portion in the −y direction) of the fourth angle limiting plate 165d.

FIG. 7 illustrates that the 1-1^{st}, 2-1^{st}, 3-1^{st}, and 4-1^{st} slits SL-a1, SL-b1, SL-c1, and SL-d1 are arranged in the same position with respect to the y direction, and the 1-2^{nd}, 2-2^{nd}, 3-2^{nd}, and 4-2^{nd} slits SL-a2, SL-b2, SL-c2, and SL-d2 are arranged in the same position with respect to the y direction. However, the disclosure is not limited thereto.

According to another embodiment, the 1-1^{st}, 2-1^{st}, 3-1^{st}, and 4-1^{st} slits SL-a1, SL-b1, SL-c1, and SL-d1 may be arranged in different positions with respect to the y direction, and the 1-2^{nd}, 2-2^{nd}, 3-2^{nd}, and 4-2^{nd} slits SL-a2, SL-b2, SL-c2, and SL-d2 may be arranged in different positions with respect to the y direction.

FIG. 7 illustrates that the slits approximately have a quadrangular shape having an angled edge. However, the disclosure is not limited thereto. According to another embodiment, the slits may approximately have a quadrangular shape having a round edge.

FIG. 7 illustrates that each of the first to fourth angle limiting plates 165a to 165d includes two slits. However, the disclosure is not limited thereto. The first to fourth angle limiting plates 165a to 165d may further define a plurality of slits having substantially the same aspects as the slits illustrated in FIG. 7.

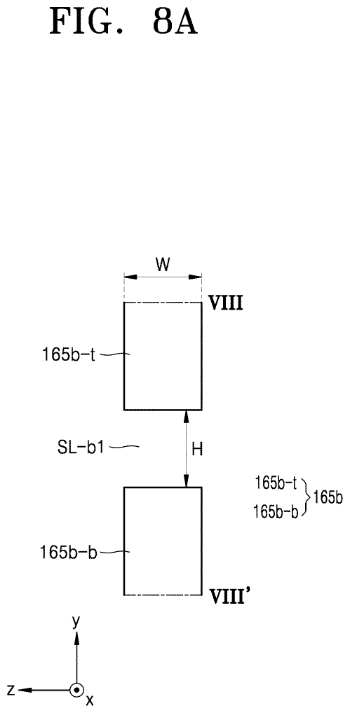

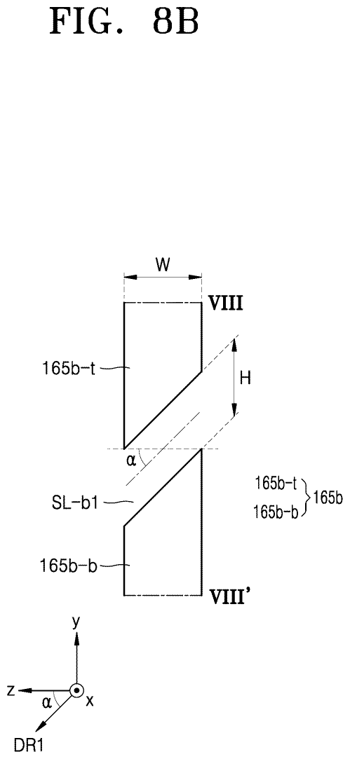

FIGS. 8A and 8B are enlarged cross-sectional views of a portion of the angle limiting plate 165 according to an embodiment.

According to an embodiment, FIGS. 8A and 8B may be cross-sectional views of the angle limiting plate 165 taken along line VIII-VIII′ of FIG. 4.

Referring to FIG. 8A, the 2-1^{st} slit SL-b1 may pass through the second angle limiting plate 165b in a ±z direction. In other words, the 2-1^{st} slit SL-b1 may be a penetration hole passing through the second angle limiting plate 165b.

A gap H between a first portion 165b-t and a second portion 165b-b of the second angle limiting plate 165b may be the same as a length H of the 2-1^{st} slit SL-b1 in a y direction.

The chamber in which deposition is performed is in a low or high vacuum state, and thus, heat transfer due to convection may be small and may be disregarded. Thus, regardless of the length H of the 2-1^{st} slit SL-b1 in the y direction, heat transfer due to convection occurring from the second portion 165b-b of the second angle limiting plate 165b to the first portion 165b-t of the second angle limiting plate 165b may be disregarded.

The possibility of transformation (for example, flexure) of the second angle limiting plate 165b may increase as the length H of the 2-1^{st} slit SL-b1 in the y direction increases. Thus, it is desirable that the length H of the 2-1^{st} slit SL-b1 in the y direction be small as much as possible.

According to an embodiment, the length H of the 2-1^{st} slit SL-b1 in the y direction may be less than or equal to a length W of the second angle limiting plate 165b in a z direction. In an embodiment, for example, the length H of the 2-1^{st} slit SL-b1 in the y direction may be the same as the length W of the second angle limiting plate 165b in the z direction.

Referring to FIG. 8B, the 2-1^{st} slit SL-b1 may pass through the second angle limiting plate 165b in a direction diagonal with respect to the ±z direction. In an embodiment, for example, the 2-1^{st} slit SL-b1 may pass through the second angle limiting plate 165b in a first direction DR1.

The length H of the 2-1^{st} slit SL-b1 in the y direction may be less than or equal to the length W of the second angle limiting plate 165b in the z direction. In an embodiment, for example, the length H of the 2-1^{st} slit SL-b1 in the y direction may be the same as the length W of the second angle limiting plate 165b in the z direction.

In a deposition process, the nozzle may be arranged in a-z direction with respect to the second angle limiting plate 165b. When a deposition material is injected by the nozzle, a portion of the injected deposition material may be dispersed and may pass through the slit of the angle limiting plate 165. Here, when the slit has the same structure as the 2-1^{st} slit SL-b1 (FIG. 8A) illustrated in FIG. 8A, most of the deposition material scattered in a +z direction may pass through the 2-1^{st} slit S1-b1 (FIG. 8A).

However, when the 2-1^{st} slit SL-b1 is formed in the first direction DR1 as illustrated in FIG. 8B, a portion of the deposition material dispersed in the +z direction may be clogged by a surface of the first portion 165b-t of the second angle limiting plate 165b and may not be dispersed to the outside. Thus, when the 2-1^{st} slit SL-b1 is formed in the first direction DR1, leakage of the deposition material may be prevented.

FIG. 8B illustrates that an end in a-y direction of the first portion 165b-t of the second angle limiting plate 165b and an end in a +y direction of the second portion 165b-b of the second angle limiting plate 165b are in the same position with respect to a y-axis. However, the disclosure is not limited thereto. According to another embodiment, the end in the −y direction of the first portion 165b-t of the second angle limiting plate 165b and the end in the +y direction of the second portion 165b-b of the second angle limiting plate 165b may be in different positions with respect to the y-axis. According to another embodiment, the first portion 165b-t and the second portion 165b-b of the second angle limiting plate 165b may partially overlap each other with respect to the y axis.

The aspects of the 2-1^{st} slit SL-b1 and the second angle limiting plate 165b are described above with reference to FIGS. 8A and 8B. However, the aspects are not limited to the 2-1^{st} slit SL-b1 and the second angle limiting plate 165b. The aspects of the 2-1^{st} slit SL-b1 and the second angle limiting plate 165b described above may be generally applied to the angle limiting plate and the slits according to various embodiments.

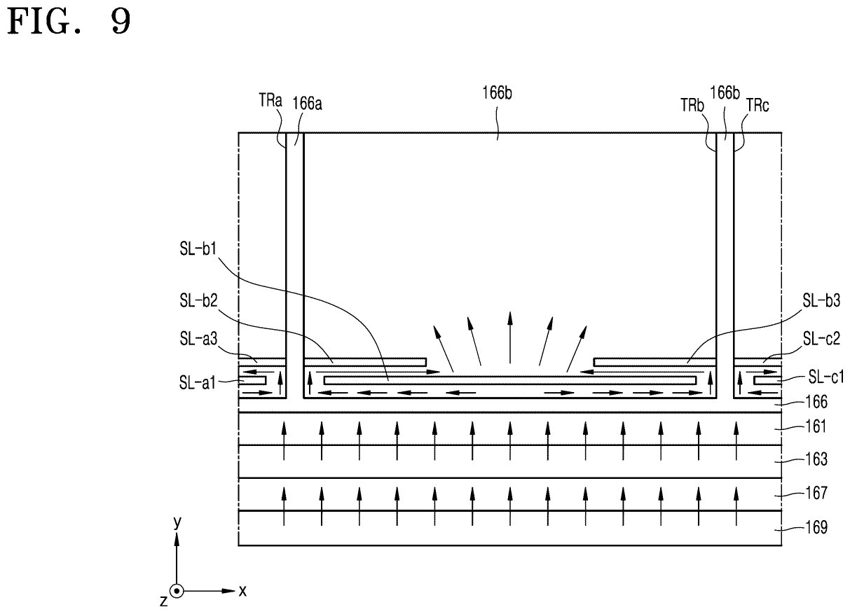

FIG. 9 is a schematic front view of a heat transfer path in the angle limiting plate 165 according to an embodiment.

In a deposition process, the chamber may be in a low vacuum state or a high vacuum state, and thus, heat transfer due to convection is small enough to be disregarded. Also, it is difficult to understand that an environment having a temperature high enough to consider heat transfer due to radiation is formed. Thus, heat transfer in the deposition source may be mostly due to conduction.

Heat transfer occurs from a high temperature to a low temperature. Accordingly, heat transfer may occur from the heat source 169 having a high temperature to the angle limiting plate 165 having a lower temperature than the heat source 169 having a high temperature. In an embodiment, for example, conductive heat transfer may occur from the heat source 169 to the body 167 adjacent to the heat source 169. Conductive heat transfer may occur from the body 167 to the bracket 163 adjacent to the body 167. Conductive heat transfer may occur from the bracket 163 to the base plate 161 adjacent to the bracket 163. Conductive heat transfer may occur from the base plate 161 to the frame 166 adjacent to the base plate 161. Conductive heat transfer may occur from the frame 166 to the second angle limiting plate 165b adjacent to the frame 166.

In a plan view, an area of the second angle limiting plate 165b may be greater than areas of the frame 166, the base plate 161, and the bracket 163. A path of heat transfer in the second angle limiting plate 165b may be altered to disrupt the conductive heat transfer.

Conductive heat transfer based on a heat transfer path may be represented by the Equation 1 below:

$$T ( x ) = ( {T}_{s , 2} - {T}_{s , 1} ) \frac{x}{L} + {T}_{s , 1} . \qquad [ Equation 1 ]$$

In the equation above, T_{s,1} may be a temperature of the heat source 169. T_{s,2} may be a temperature of the second angle limiting plate 165b at a predetermined point. L may be a length of the path of conductive heat transfer from a point having the temperature of T_{s,1} to a point having the temperature of T_{s,2}. x may be a length of the path of conductive heat transfer from the point having the temperature of T_{s,1} to a predetermined point in the path having the length of L. T(x) may be a temperature at the predetermined point described above.

Through the equation above, it may be identified that as the length of the path of conductive heat transfer increases, a temperature drop between two points may increase. In an embodiment, for example, by increasing the length of the path of conductive heat transfer in the second angle limiting plate 165b, the temperature drop may be increased. To smoothly evaporate the deposition material, the heat source 169 may have a fixed temperature. Thus, when the length of the path of conductive heat transfer in the second angle limiting plate 165b is increased, a temperature of a predetermined point of the second angle limiting plate 165b may be reduced, compared to when the length of the path of conductive heat transfer is not increased.

The 2-1^{st} to 2-3^{rd} slits SL-b1, SL-b2, and SL-b3 may curve the path of conductive heat transfer. In an embodiment, for example, the 2-1^{st} to 2-3^{rd} slits SL-b1, SL-b2, and SL-b3 arranged in the second angle limiting plate 165b may not allow conductive heat transfer to occur. Thus, conductive heat transfer may occur through a portion of the second angle limiting plate 165b, where the portion is around the 2-1^{st} to 2-3^{rd} slits SL-b1 to SL-b3 and approximately has a zigzag shape.

According to an embodiment, conductive heat transfer may take place approximately in a +y direction from the heat source 169 to the frame 166. When the 2-1^{st} to 2-3^{rd} slits SL-b1, SL-b2, and SL-b3 are not arranged, conductive heat transfer may take place approximately in the +y direction also in the second angle limiting plate 165b.

When the 2-1^{st} to 2-3^{rd} slits SL-b1 to SL-b3 are arranged, conductive heat transfer may not occur, due to the 2-1^{st} to 2-3^{rd} slits SL-b1, SL-b2, and SL-b3. The direction of conductive heat transfer may be curved at a portion of the second angle limiting plate 165b, where the portion is in a-y direction with respect to the 2-1^{st} slit SL-b1, and conductive heat transfer may continue in a +x direction. Then, the direction of conductive heat transfer may be curved at a portion of the second angle limiting plate 165b, where the portion is around the first and second protrusion portions 166a and 166b, and conductive heat transfer may take place in the +y direction. The direction of conductive heat transfer may be curved again at a portion of the second angle limiting plate 165b, where the portion is between the 2-1^{st} slit SL-b1, the 2-2^{nd} slit SL-b2, and the 2-3^{rd} slit SL-b3, and conductive heat transfer may continue again in the +x direction.

The length of the path of conductive heat transfer may be greater when the 2-1^{st} to 2-3^{rd} slits SL-b1, SL-b2, and SL-b3 are arranged than when the 2-1^{st} to 2-3^{rd} slits SL-b1, SL-b2, and SL-b3 are not arranged. Thus, when the 2-1^{st} to 2-3^{rd} slits SL-b1, SL-b2, and SL-b3 are arranged, the temperature of the entire second angle limiting plate 165b may be reduced, compared with when the 2-1^{st} to 2-3^{rd} slits SL-b1, SL-b2, and SL-b3 are not arranged.

The descriptions above are given based on the second angle limiting plate 165b. However, the aspects about the extension of the length of the path of conductive heat transfer described above may be generally applied to the angle limiting plate and the slits according to various embodiments.

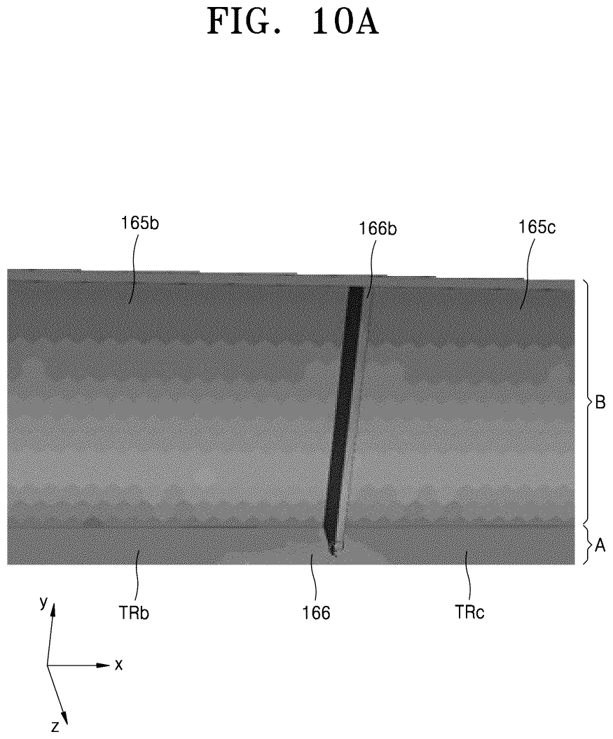

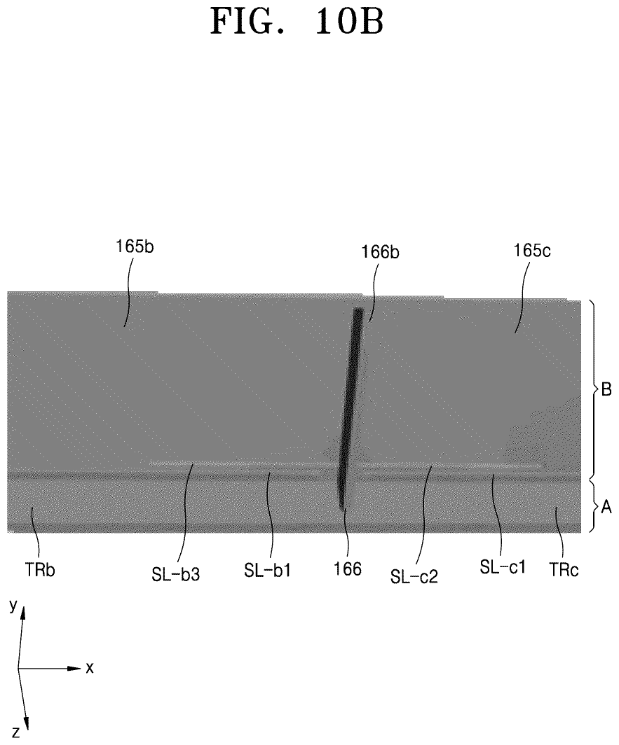

FIG. 10A is a schematic heat distribution diagram of a frame and an angle limiting plate to which a slit according to the disclosure is not applied.

Referring to FIG. 10A, when the slit is not applied to the angle limiting plate, conductive heat transfer from a heat source arranged below the frame 166 to the frame 166, the second angle limiting plate 165b, and the third angle limiting plate 165c may occur in a +y direction. In this case, the second and third angle limiting plates 165b and 165c may have heat distribution as illustrated in FIG. 10A.

A portion of the frame 166 or a portion A may have a higher temperature than the second and third angle limiting plates 165b and 165c. In an embodiment, for example, the portion A may have a higher temperature than a portion B at which the second and third angle limiting plates 165b and 165c are arranged.

According to an embodiment, a temperature of the portion A may be about 280° C. to about 300° C. A temperature of the portion B may be about 200° C. to about 280° C. However, the disclosure is not limited to these numerical values.

The temperature of the portion B may be decreased in a +y direction. In an embodiment, for example, a temperature of a point at which the second and third angle limiting plates 165b and 165c contact the frame 166 or a boundary between the portion A and the portion B may be the highest in the portion B. Temperatures of surfaces in the ty direction of the second and third angle limiting plates 165b and 165c may be the lowest in the portion B.

FIG. 10B is a schematic heat distribution diagram of a frame and an angle limiting plate to which a slit according to the disclosure is applied.

Referring to FIG. 10B, the second angle limiting plate 165b may define a 2-1^{st} slit SL-b1 and a 2-3^{rd} slit SL-b3. The third angle limiting plate 165c may define a 3-1^{st} slit SL-c1 and a 3-2^{nd} slit SL-c2.

When the 2-1^{st}, 2-3^{rd}, 3-1^{st}, and 3-2^{nd} slits SL-b1, SL-b3, SL-c1, and SL-c3 are applied to the second and third angle limiting plates 165b and 166c, conductive heat transfer from a heat source to the frame 166, the second angle limiting plate 165b, and the third angle limiting plate 166c may be interrupted. By interrupting conductive heat transfer through the second and third angle limiting plates 165b and 166c, the temperature of the second and third angle limiting plates 165b and 166 may be reduced. In this case, the second and third angle limiting plates 165b and 165c may have heat distribution as illustrated in FIG. 10B.

A portion of the frame 166 or a portion A may have a higher temperature than the second and third angle limiting plates 165b and 165c. In an embodiment, for example, the portion A may have a higher temperature than a portion B at which the second and third angle limiting plates 165b and 165c are arranged.

According to an embodiment, a temperature of the portion A may be about 200° C. to about 210° C. A temperature of the portion B may be about 190° C. to about 200° C.

The temperature of the portion B may be decreased in a +y direction. In an embodiment, for example, a temperature of a point at which the second and third angle limiting plates 165b and 165c contact the frame 166 or a boundary between the portion A and the portion B may be the highest in the portion B. Temperatures of surfaces in the +y direction of the second and third angle limiting plates 165b and 165c may be the lowest in the portion B.

When the slit is arranged, there may be a difference between the temperature of the portion A and the temperature of the portion B, but the width the difference may be smaller than when the slit is not applied.

In an embodiment, for example, when the slit is not applied, the highest temperature of the portion A may be about 300° C., and the lowest temperature of the portion B may be about 200° C. When the slit is not applied, the difference between the highest temperature of the portion A and the lowest temperature of the portion B may be about 100° C.

When the slit is applied, the highest temperature of the portion A may be about 200° C., and the lowest temperature of the portion B may be about 180° C. When the slit is applied, the difference between the highest temperature of the portion A and the lowest temperature of the portion B may be about 20° C.

Thus, when the slit is applied, the difference between the highest temperature of the portion A and the lowest temperature of the portion B may be less than when the slit is not applied.

When the slit is not applied, the temperature of the portion B may be about 200° C. to about 280° C.

When the slit is applied, the temperature of the portion B may be about 180° C. to about 200° C.

Thus, when the slit is applied, the temperature of the portion B may be lower than when the slit is not applied.

An example of temperature distribution is described above to explain the aspects of the disclosure that the temperature of the angle limiting plate may be reduced when the slit is applied. However, the disclosure is not limited to the described numerical values.

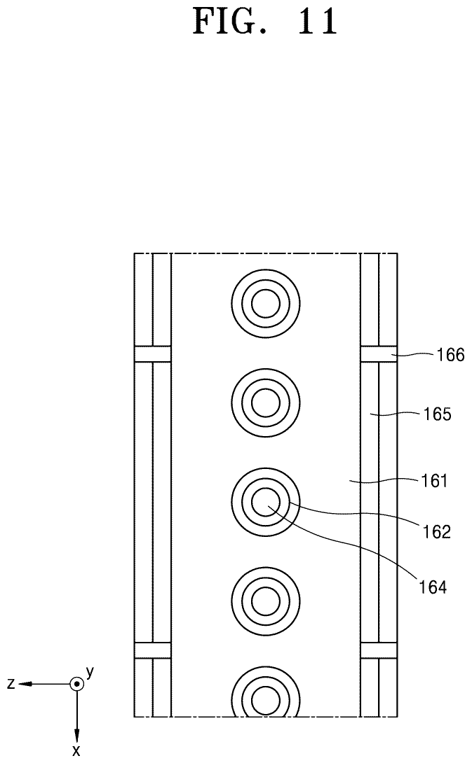

FIG. 11 is a schematic plan view of a portion of the apparatus 2 for manufacturing a display apparatus, according to an embodiment.

Referring to FIG. 11, the angle limiting plate 165 and the frame 166 may have a linear shape in a direction (for example, a +x direction).

The plurality of angle limiting plates 165 and the plurality of frames 166 may be arranged to face each other with the nozzle 164, the reflector 162, and the base plate 161 therebetween. In other words, the nozzle 164, the reflector 162, and the base plate 161 may be arranged between the plurality of angle limiting plates 165 and the plurality of frames 166.

The base plate 161 may include an opening exposing a portion of the reflector 162 and a portion of the nozzle 164. The reflector 162 may include an opening exposing a portion of the nozzle 164. A portion of the nozzle 164 may protrude in a +y direction through the opening of the base plate 161 and the opening of the reflector 162.

A side surface of the opening of the base plate 161 may be spaced apart from a side surface of the nozzle 164. A side surface of the opening of the reflector 162 may be spaced apart from the side surface of the nozzle 164.

The plurality of nozzles 164 may be serially arranged between the plurality of angle limiting plates 165. In an embodiment, for example, the plurality of nozzles 164 may be serially arranged in the +x direction between the angle limiting plates 165.

FIG. 11 illustrates that around 3 nozzles 164 are arranged between two angle limiting plates 165. However, the disclosure is not limited thereto. The number of nozzles 164 arranged between the angle limiting plates 165 is not particularly limited.

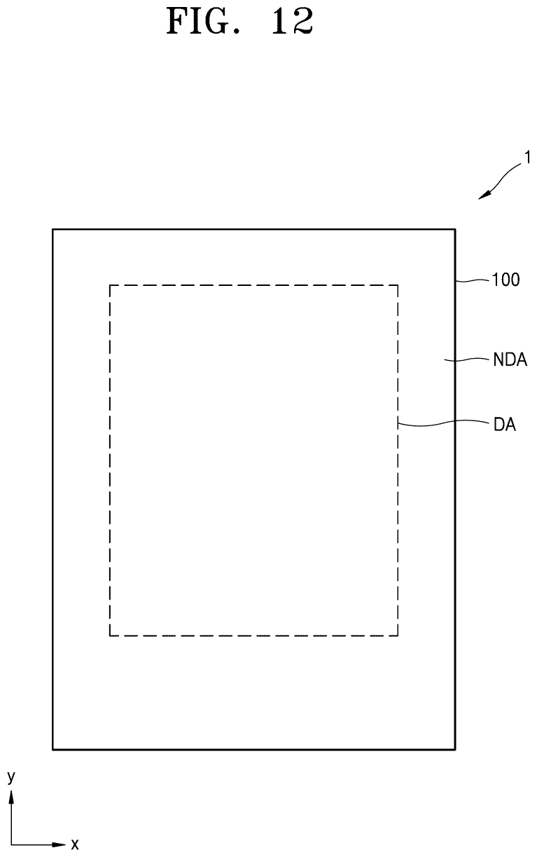

FIG. 12 is a schematic plan view of a display apparatus 1 which may be manufactured by the apparatus 2 for manufacturing a display apparatus, according to an embodiment.

Referring to FIG. 12, the display apparatus 1 may include a substrate 100 including a display area DA and a non-display area NDA. Sub-pixels including a display element such as a light-emitting diode may be arranged in the display area DA and may provide a certain image. The non-display area NDA may be an area which may not provide an image. The non-display area NDA may surround the display area DA. A scan driver and a data driver configured to provide an electrical signal to be applied to the sub-pixels of the display area DA and power lines configured to provide a power supply such as a driving voltage and a common voltage may be arranged in the non-display area NDA.

FIG. 12 illustrates that a length of the display apparatus 1 in a ±x direction is less than a length of the display apparatus 1 in a ±y direction. However, the disclosure is not limited thereto. According to another embodiment, the length of the display apparatus 1 in the ±x direction may be greater than the length of the display apparatus 1 in the ±y direction. Like this, the shape of the display apparatus 1 may be variously modified.

The display apparatus 1 may include various products, such as a mobile phone, a smartphone, a tablet personal computer (“PC”), a mobile communication terminal, an electronic notebook, an electronic book, a portable multimedia player (“PMP”), a navigation device, an ultra-mobile PC (“UMPC”), a television, a notebook computer, a monitor, an advertising board, an Internet of things (“IoT”) device, etc. Also, the display apparatus 1 according to an embodiment may be used in wearable devices, such as a smart watch, a watch phone, a glasses-type display, and a head-mounted display (“HMD”). Also, the display apparatus 1 according to an embodiment may be used as: a center information display (“CID”) on a gauge of a vehicle or a center fascia or a dashboard of the vehicle; a room mirror display substituting a side-view mirror of a vehicle; or a display screen disposed on a rear surface of a front seat, as an entertainment device for a backseat of a vehicle.

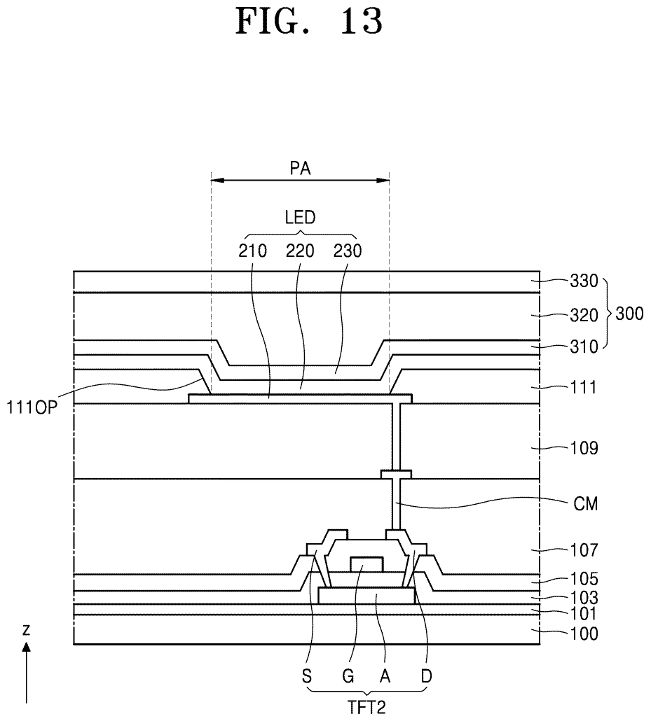

FIG. 13 is a schematic cross-sectional view of a portion of the display apparatus 1 which may be manufactured by the apparatus 2 for manufacturing a display apparatus, according to an embodiment.

Referring to FIG. 13, a light-emitting diode LED corresponding to the sub-pixel arranged in the display area DA may be provided on the substrate 100. The light-emitting diode LED may be electrically connected to a thin-film transistor TFT.

The thin-film transistor TFT may include an active layer A, a gate electrode G overlapping a portion of the active layer A, a source electrode S, and a drain electrode D, where the source electrode S and the drain electrode D are connected to the active layer A. The gate electrode G may include at least one material selected from Al, Pt, Pd, Ag, Mg, Au, Ni, Nd, Ir, Cr, Li, Ca, Mo, Ti, W, and Cu and may include a single layer or layers including the material described above.

A buffer layer 101 for preventing penetration of impurities may be arranged between the active layer A and the substrate 100. A gate insulating layer 103 may be arranged between the active layer A and the gate electrode G. An interlayer insulating layer 105 may be arranged on the gate electrode G. Each of the buffer layer 101, the gate insulating layer 103, and the interlayer insulating layer 105 may include an inorganic insulating material, such as SiOₓ, SiNₓ, SiON, AlOₓ, AlNₓ, TiOₓ, or TiNₓ.

The source electrode S and the drain electrode D may be arranged on the interlayer insulating layer 105 and may be connected to the active layer A through a contact hole formed in the interlayer insulating layer 105 and the gate insulating layer 103. The source electrode S and the drain electrode D may include at least one of Al, Pt, Pd, Ag, Mg, Au, Ni, Nd, Ir, Cr, Li, Ca, Mo, Ti, W, and Cu and may include a single layer or layers.

A first organic insulating layer 107 may be arranged on the thin-film transistor TFT. The first organic insulating layer 107 may include an organic insulating material, such as acryl, benzocyclobutene (“BCB”), polyimide (“PI”), or hexamethyldisiloxane (“HMDSO”).

A contact metal CM may be arranged on the first organic insulating layer 107. The contact metal CM may include Al, Cu, and/or Ti and may include a single layer or layers including the materials described above.

A second organic insulating layer 109 may be arranged between the contact metal CM and a sub-pixel electrode 210. The second organic insulating layer 109 may include an organic insulating material, such as acryl, BCB, PI, or HMDSO. According to an embodiment described with reference to FIG. 13, the thin-film transistor TFT and the sub-pixel electrode 210 are electrically connected to each other through the contact metal CM. However, according to another embodiment, the contact metal CM may be omitted, and one organic insulating layer may be arranged between the thin-film transistor TFT and the sub-pixel electrode 210. Alternatively, three or more organic insulating layers may be arranged between the thin-film transistor TFT and the sub-pixel electrode 210, and the thin-film transistor TFT and the sub-pixel electrode 210 may be electrically connected to each other through a plurality of contact metals.

The sub-pixel electrode 210 may be arranged on the second organic insulating layer 109. The sub-pixel electrode 210 may include a transparent or half-transparent electrode or may include a reflection electrode. When the sub-pixel electrode 210 includes a transparent or half-transparent electrode, the sub-pixel electrode 210 may include, for example, ITO, IZO, ZnO, In₂O₃, IGO, or AlZO. When the sub-pixel electrode 210 includes a reflection electrode, the sub-pixel electrode 210 may include a reflection layer including Ag, Mg, Al, Pt, Pd, Au, Ni, Nd, Ir, Cr, or a compound thereof and may further include, on the reflection layer, a layer including ITO, IZO, ZnO, or In₂O₃. According to an embodiment, the sub-pixel electrode 210 may have a structure in which an ITO layer, an Ag layer, and an ITO layer are sequentially stacked. However, the disclosure is not limited thereto, and the sub-pixel electrode 210 may be variously modified. In an embodiment, for example, the sub-pixel electrode 210 may include various materials, and the sub-pixel electrode 210 may include a single layer or layers. The sub-pixel electrode 210 may be electrically connected to the contact metal CM through a contact hole formed in the second organic insulating layer 109.

A sub-pixel defining layer 111 may cover a boundary portion (or an edge) of the sub-pixel electrode 210. The sub-pixel defining layer 111 may include an opening 111-OP exposing a portion of the sub-pixel electrode 210. The opening 111-OP of the sub-pixel defining layer 111 may correspond to an area where the light of the light-emitting diode LED is emitted and may define an emission area of a sub-pixel or the light-emitting diode LED.

An intermediate layer 220 may be arranged on the sub-pixel electrode 210. The intermediate layer 220 may include an organic emission layer including a low molecular-weight material or a high molecular-weight material. The intermediate layer 220 may have a structure including a single layer or layers of a hole injection layer (“HIL”), a hole transport layer (“HTL”), an organic emission layer (“EML”), an electron transport layer (“ETL”), and/or an electron injection layer (“EIL”).

An opposite electrode 230 may be arranged on the intermediate layer 220. The opposite electrode 230 may include a transparent/half-transparent electrode. When the opposite electrode 230 includes a transparent/half-transparent electrode, the opposite electrode 230 may include one or more materials selected from Ag, Al, Mg, Li, Ca, Cu, LiF/Ca, LiF/AI, MgAg, and CaAg and may be formed as a thin film having a thickness of several to dozens nms. The structure and the material of the opposite electrode 230 are not limited thereto, and various modifications are possible.

An encapsulation layer 300 may be arranged on the opposite electrode 230. The encapsulation layer 300 may include at least one inorganic encapsulation layer and at least one organic encapsulation layer. In an embodiment, for example, the encapsulation layer 300 may include a first inorganic encapsulation layer 310, a second inorganic encapsulation layer 330, and an organic encapsulation layer 320 therebetween. The first and second inorganic encapsulation layers 310 and 330 may include an inorganic insulating material, such as SiOₓ, SiNₓ, and SiON, and the organic encapsulation layer 320 may include at least one organic insulating material selected from polyethylene terephthalate (“PET”), polyethylene naphthalate (“PEN”), polycarbonate (“PC”), polyimide (“PI”), polyethylene sulfonate (“PES”), polyoxymethylene (“POM”), polyarylate (“PAR”), and HMDSO.

As described above, according to an apparatus for manufacturing a display apparatus and a method of manufacturing a display apparatus according to an embodiment, a path of conductive heat transfer in an angle limiting plate may be extended through a plurality of slits formed in the angle limiting plate, and thus, the angle limiting plate may generally have a decreased temperature.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. An apparatus for manufacturing a display apparatus, the apparatus comprising:
an evaporation source including a nozzle configured to spray a deposition material;
a first frame arranged on the evaporation source and defining a trench therein; and
a first angle limiting plate arranged in the trench of the first frame and defining a plurality of slits therein,
wherein the trench is arranged in a lengthwise direction of the first frame.

2. The apparatus of claim 1, wherein the trench of the first frame passes through the first frame in a thickness direction of the first frame.

3. The apparatus of claim 1, wherein a thickness of the first frame is greater than a thickness of the first angle limiting plate.

4. The apparatus of claim 1, wherein the first angle limiting plate defines a first slit extending from a central portion of the first angle limiting plate toward a side surface of the first angle limiting plate, and the plurality of slits includes the first slit.

5. The apparatus of claim 1, wherein the first angle limiting plate defines a second slit extending from an edge of a first side surface of the first angle limiting plate toward a central portion of the first angle limiting plate, and the plurality of slits includes the second slit.

6. The apparatus of claim 5, wherein the first angle limiting plate further defines a third slit extending from an edge of a second side surface of the first angle limiting plate toward the central portion of the first angle limiting plate, the second side surface is opposite to the first side surface, and the plurality of slits includes the third slit.

7. The apparatus of claim 1, wherein at least one of the plurality of slits passes through the first angle limiting plate in a direction that is diagonal with respect to a thickness direction of the first angle limiting plate.

8. The apparatus of claim 1, further comprising:
a second frame arranged on the evaporation source to face the first frame with the nozzle between the second frame and the first frame, where the second frame defines a trench therein; and
a second angle limiting plate arranged in the trench of the second frame and defining another plurality of slits therein,
wherein the trench of the second frame is arranged in a lengthwise direction of the second frame.

9. The apparatus of claim 8, wherein the first and second angle limiting plates are linear shaped in a certain direction,
the evaporation source is provided in plurality,
the plurality of the evaporation sources are serially arranged in the lengthwise direction of the first frame and disposed between the first and second angle limiting plates.

10. The apparatus of claim 1, wherein the evaporation source includes:
a crucible arranged below the nozzle;
a heat source arranged to be adjacent to the crucible; and
a cover arranged on the crucible and the heat source and defining an opening overlapping the nozzle.

11. The apparatus of claim 10, wherein the nozzle and the cover are arranged to be spaced apart from each other.

12. A method of manufacturing a display apparatus, the method comprising:
preparing an object to be processed;
preparing an evaporation source capable of storing a deposition material;
heating the deposition material by using a heat source provided in the evaporation source; and
depositing the heated deposition material on the object to be processed by spraying the heated deposition material toward the object to be processed,
wherein a frame arranged on the evaporation source and defining a trench therein, and
an angle limiting plate arranged in the trench of the frame and defining a plurality of slits are used in the method.

13. The method of claim 12, wherein, in the depositing of the heated deposition material on the object to be processed by spraying the heated deposition material, a spraying angle of the heated deposition material is limited by the angle limiting plate.

14. The method of claim 12, wherein the angle limiting plate defines a first slit extending from a central portion of the angle limiting plate toward a side surface of the angle limiting plate, and the plurality of slits includes the first slit.

15. The method of claim 12, wherein the angle limiting plate defines a second slit extending from an edge of a first side surface of the angle limiting plate toward a central portion of the angle limiting plate, and the plurality of slits includes the second slit.

16. The method of claim 15, wherein the angle limiting plate further defines a third slit extending from an edge of a second side surface of the first angle limiting plate toward the central portion of the angle limiting plate, the second side surface is opposite to the first side surface, and the plurality of slits includes the third slit.

17. The method of claim 12, wherein the plurality of slits disrupt heat transfer through the angle limiting plate.

18. The method of claim 12, wherein at least one of the plurality of slits passes through the angle limiting plate in a direction that is diagonal with respect to a thickness direction of the angle limiting plate.

19. The method of claim 12, wherein, in the depositing of the heated deposition material on the object to be processed by spraying the heated deposition material, at least a portion of the heated deposition material does not pass through the plurality of slits of the angle limiting plate.

20. The method of claim 12, wherein the angle limiting plate is linear shaped in a certain direction, and
in the depositing of the heated deposition material on the object to be processed by spraying the heated deposition material, the object to be processed is moved, with respect to the evaporation source, in a direction which is perpendicular to the certain direction.
